(19) United States
(12) Patent Application Publication
(10) Pub. No.: US 2016/0124065 A1
(43) Pub. Date: May 5, 2016

(54) METHOD AND APPARATUS FOR CORRECTION OF MAGNETIC RESONANCE IMAGE RECORDINGS WITH THE USE OF A CONVERTED FIELD MAP

(71) Applicant: Siemens Aktiengesellschaft, Muenchen (DE)

(72) Inventors: Josef Pfeuffer, Kunreuth (DE); Mario Zeller, Erlangen (DE)

(73) Assignee: SIEMENS AKTIENGESELLSCHAFT, Muenchen (DE)

(21) Appl. No.: 14/932,235

(22) Filed: Nov. 4, 2015

(30) Foreign Application Priority Data
Nov. 4, 2014 (DE) 102014222495.0

(51) Int. Cl. G01R 33/565; G01R 33/561

(52) U.S. Cl. CPC G01R 33/56563; G01R 33/5616

(57) ABSTRACT

In a method and device for the correction of image data acquired using a magnetic resonance imaging method, an undistorted field map is recorded. The undistorted field map is then converted into a distorted field map. Image data recorded with distorted coordinates are corrected with the use of the distorted field map.

### BACKGROUND OF THE INVENTION

1. Field of the Invention

The invention concerns a method for the correction of image data acquired with a magnetic resonance imaging method. The invention also concerns a method for magnetic resonance imaging. The invention also concerns an image correction device for a magnetic resonance measurement. The invention further relates to a magnetic resonance apparatus.

2. Description of the Prior Art

In a magnetic resonance system, the body to be examined is usually exposed to a relatively strong basic magnetic field, for example 1.5 tesla, 3 tesla or 7 tesla with the use of a basic field magnet. After the application of the basic field, nuclei in the object under examination align along the field with a non-zero magnetic dipole moment, called spin. This collective behavior of the spin system is described as macroscopic “magnetization”. Macroscopic magnetization is the vector sum of all microscopic magnetic moments at a specific location in the object. In addition to the basic field, a gradient system applies a magnetic field gradient enabling the magnetic resonance frequency (Larmor frequency) at the respective location to be determined. A radio-frequency transmission system then emits radio-frequency excitation signals (RF pulses) by appropriate antenna devices in order to cause the macroscopic “magnetization” to be tilted by a defined flip angle with respect to the magnetic field lines of the basic magnetic field. When such an RF pulse has an effect on spins that are already excited, these can be tilted into a different angular position or even swung back into an original position parallel to the basic magnetic field. Upon relaxation of the excited nuclear spins, radio-frequency signals, called magnetic resonance signals, are resonantly emitted and received by suitable receiving antennas (also known as magnetic resonance coils or receiving coils). The received signals subsequently demodulated and digitized and then further processed as so-called “raw data”. The acquisition of the magnetic resonance signals takes place in the spatial frequency domain, called “k-space”, wherein, during a measurement of a slice, for example, k-space is filled with data at respective data entry points chronologically along a gradient trajectory (also called “k-space trajectory”), of the points, defined by the switching of the gradient pulses. The RF pulses have to be emitted in temporally appropriate coordination therewith. After further procedural steps, which usually also depend on the acquisition method, the desired image data can finally be reconstructed from the raw data acquired in this way, by a two-dimensional

Fourier transformation. Alternatively, it is possible in the interim to excite and read-out three-dimensional volumes, in a defined manner, wherein, again after further procedural steps, the raw data are sorted into three-dimensional k-space. Correspondingly, it is then possible to reconstruct a three-dimensional image data volume by a three-dimensional Fourier transformation.

Usually, prespecified pulse sequences, i.e. sequences of defined RF pulses and gradient pulses in different directions and with readout windows, during which the receiving antennas are switched to receive and the magnetic resonance signals are received and processed, are used to control a magnetic resonance tomography scanner during the measurement (data acquisition). With the use of a so-called measurement protocol, these sequences are parameterized in advance for a desired examination, for example a specific contrast of the calculated images. The measurement protocol can also include further control data for the measurement. A large number of magnetic resonance sequence techniques are suitable for constructing pulse sequences. One of the great challenges facing the future development of magnetic resonance imaging (MR imaging) is the acceleration of magnetic resonance sequence techniques without significant compromises with respect to resolution, contrast and the occurrence of artifacts.

For complete image information, it is necessary to fill (scan) all grid points in k-space. With normal imaging methods, this takes place line-by-line. This means that n lines have to be measured one after the other. Therefore, the measuring time is determined by the resolution of the matrix with which the measurement in the k-space is performed, as well as by the repetition time.

With magnetic resonance sequences, it is possible to differentiate between spin echo sequences and gradient echo sequences. The basic difference between the two types of sequence is that, with spin echo sequences, refocusing of the nuclear spins is achieved by the radiation of an RF pulse in order to produce an echo, i.e. a resonant measuring signal and, with the gradient echo sequences, an additional gradient is switched (activated) to generate an echo.

When using gradient echo sequences, a measuring gradient is switched simultaneously with the phase-encoding gradients. This measuring gradient generates an additional inhomogeneity resulting in more rapid dephasing of the transverse component. This effect is compensated by a subsequent measuring gradient with the opposite polarity. This also results in an echo signal, a so-called gradient echo. In other words, with gradient echo sequences, instead of the RF pulse, an additional gradient with the opposite polarity to that of a previously switched dephasing gradient is switched so that the gradient echo sequence results in rephasing of the nuclear spins, which can be acquired by the receiving antennas as a measuring signal or echo signal.

Gradient echo sequences enable shorter measuring times to be achieved because, with the use of gradient echo sequences, the echo time and the repetition time are shorter than with the spin echo method. This can be attributed to the fact that, with gradient echo sequences, no refocusing RF pulse is required.

However, because with gradient echo sequences, the rephasing of the nuclear spins with the aid of an additionally switched gradient with the opposite polarity sign from that of a dephasing gradient only results the cancellation of the dephasing gradient, and with gradient echo sequences, no refocusing RF pulse is radiated, the effect of magnetic field inhomogeneities, such as caused by changes in susceptibility, on the dephasing of the spins is retained.

For this reason, changes in susceptibility and external magnetic field inhomogeneities with gradient echo sequences result in location-dependent (spatially dependent) temporal accumulations that are identified as image artifacts. For example, this may result in intravoxel dephasing with the subsequent erasure (blanking out) of entire areas of the image.

With the type of data acquisition known as echo planar imaging (EPI), multiple phase-encoded echoes are used to fill a slice in k-space, also known as a raw-data matrix. The basic concept of this technique is to make an individual (selective) RF excitation of nuclear spins in a slice, followed by the generation of a series of echoes in the readout gradients, which are assigned to different lines in k-space by means of suitable modulation of the phase-encoding gradients. This enables, for example, the acquisition of an entire slice with a single RF excitation.

With echo planar imaging, the long echo train also causes geometric distortion to develop in the image, such as, for example, dilations or compressions. These are also referred to collectively as distortion in the following.

One possibility for reducing such artifacts is to reduce the phase accumulation by, for example, improving the overall homogeneity of the basic magnetic field.

Alternatively or additionally, the phase accumulation can be diminished by reducing the readout time. This can be achieved by smaller matrix sizes, i.e. reduced resolution, parallel imaging, or segmented recording.

Such artifacts also can be eliminated by retrospective methods. These take effect only after following the recording of the raw data, i.e., in the reconstruction process. With this type of post-acquisition treatment, usually a separate field map, also called a B₀ field map, is recorded, which can have map values organized with either undistorted coordinates or distorted coordinates.

Field maps show the spatial distribution of effects of off-resonance frequencies. Off-resonance frequencies mean frequency shifts of the measuring signals, which occur due to the aforementioned susceptibility changes and external magnetic field inhomogeneities.

Undistorted field maps can be obtained, for example, from the different phase of recordings of undistorted sequences with a different echo time, for example, by phase difference separation from a gradient echo sequence with two recordings (e.g. Jezzard et al., 1995, MRM 34:65-73), three recordings assuming a model and solution of an optimization problem (Dagher et al., 2013, MRM 71:105-117), or an EPI sequence modified into a multi-echo gradient echo sequence and autocorrelation of the phase development (Schmithorst et al., 2001, IEEE transactions on medical imaging 20:535-539). From undistorted maps, it can be derived where an object point will be depicted in the image that is recorded.

Distorted maps are obtained from recordings that also include distortion, for example from the phase difference of two EPI recordings with which the recording times of the individual k-space lines are displaced by a small offset with respect to each other, as occurs, for example, with the PLACE method (phase labeling for additional coordinate encoding, Xiang et al., 2007, MRM 57:731-741). This recording procedure has a significant time advantage for undistorted maps compared to the recording procedures known to date. However, since the maps are obtained from EPI recordings, they already include the geometric distortion, i.e. the map entries have distorted coordinates. These maps may be used to determine the object point from which a point in the image originates. FIG. 1 provides a schematic overview of undistorted and distorted recordings and field maps.

Hence, the two maps are not equivalent so that the applicable correction methods also differ. A correction with the use of undistorted maps can be performed, for example, with the use of multi-frequency interpolation, a conjugate phase method in the k-space (e.g. Man et al., 1997. MRM 37:785-792, see FIG. 2). In simplified terms, in this case, a discretized number of off-resonance frequencies is obtained from the undistorted field map. Then, the k-space of the distorted image for each of these frequencies is multiplied with a linear phase ramp that has a steepness that is determined by the negative frequency. Following Fourier transformation of the k-spaces multiplied with the individual phase ramps into the image domain, the final corrected image is assembled as follows. The off-resonance frequency is derived pixel-by-pixel from the field map and the previously reconstructed image with an assigned frequency closest to that chosen is selected. From this image, the grey value is obtained at this position and written to the new target image. This is repeated until all pixels in the field map have been passed through. The advantage of this method is that it can be applied to any k-space trajectories and is not restricted to Cartesian recordings.

A correction based on a distorted map correction can be performed, for example, in the image domain as follows. At each pixel position, the value of the displacement in the distorted displacement map (=distorted field map) is read out and the grey value present in the distorted image at this pixel position is displaced by this displacement value to its original (and hence undistorted) position, for example, by bilinear interpolation (Xiang et al., 2007, MRM 57:731-741, see FIG. 3).

Undistorted maps usually contain more information because they do not yet have any dilated or compressed regions.

To this end, the recording of distorted maps, for example, with the PLACE method, can take place “on the fly” with EPI measurements repeated once or several times e.g. during an fMRI procedure (see Pfeuffer and Vogler, DE 10 2008 007 048). This enables changed conditions, for example, movement of the patient, to be taken into account. In addition, simultaneous use of the data for the actual imaging process is possible and therefore, the measuring time is not prolonged.

However, it is not normally practicable to record an undistorted field map during an EPI measurement that is repeated several times, because this requires the EPI recording to be interrupted.

Distorted maps obtained with the PLACE method have the drawback that they are generally sensitive to phase changes (e.g. due to different respiratory conditions between the two EPI recordings used for a PLACE map) (Zeller et al., 2014, MRM 72:446-451)

Therefore, there are both different types of field maps (distorted and undistorted) and an extremely large variety of correction algorithms. These algorithms are each defined for a type of field map. Since both the two field map types and the correction algorithms have different advantages and drawbacks, a flexible combination of any field map type with any algorithm is desirable. For example, the conjugate phase method has the advantage that it can be used in combination with sequences with any form of k-space trajectory. The PLACE method as a method for the generation of distorted field maps has the advantage that it can be used simultaneously or “on the fly” for an EPI recording, which cannot be interrupted.

In addition to the “on-the-fly” generation of the field map, with which the actual EPI recording cannot be interrupted, the field map can also be continuously updated, for example, in the case of fMRI scans. Otherwise, the advantage of the PLACE method is that no other method apart from the PLACE method is able to achieve a field map with identical resolution in a similarly short time.

### SUMMARY OF THE INVENTION

It is therefore an object of the present invention to provide a method that enables the correction of any correction algorithm with any type of field map.

A basic underlying concept of the method according to the invention is to make field map conversions in both directions, i.e. from a distorted field map into an undistorted field map, and vice versa, from an undistorted field map into a distorted field map. A further insight on which the invention is based is that the correction of a distorted image recording with the use of field maps that involve the conversion of a field map of one kind into field map of the other kind is not restricted to methods such as, for example, k-space-based multi-frequency interpolation, but it is also possible to use other methods, such as, for example, bilinear interpolation, for the correction of the distorted image recording and vice versa. In this way, there is freedom of choice both during the recording of the field maps and also during the performance of the correction of distorted image recordings with respect to the use of the corresponding methods.

With the method according to the invention for the correction of image data acquired using a magnetic resonance imaging method, first, an undistorted B₀ field map is recorded. This can be done, for example, with the use of phase difference formation from a gradient echo sequence with two recordings or another recording method suitable for this purpose. The undistorted B₀ field map is then converted into a distorted B₀ field map. Finally, image data recorded with distorted coordinates, i.e. also for example with the EPI method, are corrected with the use of the distorted B₀ field map.

With the method according to the invention for magnetic resonance imaging, image data with distorted coordinates are acquired, for example with an EPI sequence. The method according to the invention for the correction of image data acquired using a magnetic resonance imaging method is applied to the acquired image data.

The image correction device according to the invention has a control sequence-generating processor configured to generate a control sequence with a first partial sequence for the generation of undistorted magnetic resonance raw data from a region of an object under examination, and with a second partial sequence for the generation of distorted magnetic resonance raw data from a region of the object under examination during acquisition of the raw MR data. The first partial sequence can be composed of multiple gradient echo sequences, for example. The second partial sequence can be composed of an EPI sequence, for example. The image correction device according to the invention also has an image reconstruction processor configured to determine image data on the basis of the magnetic resonance raw data image data acquired. It also has a field map generating processor configured to compile an undistorted field map on the basis of the undistorted image data determined. The image correction device further has a field map conversion processor configured to convert the undistorted field map into a distorted field map. Finally, the image correction device has an image correction processor configured to perform an image correction on the basis of the distorted magnetic resonance image data determined and taking account of the distorted B₀ field map. The term “processor” does not necessarily mean a standalone component; all such “processors” can be modules of an overall processor to computer

If the field map contains at one position, for example, a distortion of 3 pixels, the corresponding pixel for the new distorted field map is displaced by 3 pixels. The original unit of the field map is a frequency that can be converted into a B₀ inhomogeneity or a pixel value (see also Jezzard et al. 1995, MRM 34:65-73).

The magnetic resonance apparatus according to the invention includes the image correction device according to the invention. The image correction device according to the invention is therefore a component of the magnetic resonance apparatus. It can be part of an otherwise existing control computer, reconstruction computer or evaluation computer, for example.

The aforementioned and possibly further units do not have to be embodied as hardware components, but can also be implemented as software modules, for example if the described functions can be carried out by other components already implemented on the same device, such as, for example, a central processor or an existing control computer. Similarly, such units can be formed of hardware and software components, such as, for example, a standard hardware component that is specially configured by software for the specific intended purpose. It is also possible for several units to be combined in a common unit.

The present invention also encompasses a non-transitory, computer-readable data storage medium encoded with programming instructions, which can be loaded directly into a processor of a magnetic resonance apparatus. The processor, when the programming instructions are executed therein, causes the method as described to be implemented.

In a preferred embodiment of the method according to the invention for the correction of image data acquired using a magnetic resonance imaging method, during the conversion stage of the undistorted field map into a distorted field map, a bilinear interpolation or a conjugate phase method is performed. With bilinear interpolation, linear interpolation in two dimensions is performed in a two-dimensional coordinate system. In this case, interpolation is initially performed twice between function values of in each case two grid points in one direction and then between the resulting two interpolation values in the other direction.

In another embodiment of the method according to the invention, following the correction step, the image data recorded with distorted coordinates are corrected with the aid of bilinear interpolation.

In another preferred embodiment of the method according to the invention, the undistorted B₀ field map is compiled with the use of a gradient echo data acquisition sequence.

In another embodiment of the method according to the invention, a double-echo or multi-echo gradient echo acquisition sequence is used as the image acquisition sequence to acquire the undistorted B₀ field map.

As a further alternative, the recording of the undistorted B₀ field map can be performed during an adjustment procedure implemented before the recording of the distorted image data.

With the method according to the invention for magnetic resonance imaging, an image recording method with an EPI sequence can be used to acquire the image data with distorted coordinates.

### BRIEF DESCRIPTION OF THE DRAWINGS

FIG. 1 schematically illustrates a field map in each case in distorted and undistorted coordinates and in each case an undistorted gradient echo recording and a distorted echo planar recording.

FIG. 2 shows the geometric correction of a distorted recording on the basis of an undistorted field map.

FIG. 3 shows the correction of a distorted image recording with the aid of a distorted field map.

FIG. 4 shows the conversion of a distorted field map into an undistorted field map.

FIG. 5 shows the conversion of an undistorted field map into a distorted field map according to an exemplary embodiment of the invention.

FIG. 6 is a flowchart illustrating a method for the correction of image data acquired using a magnetic resonance imaging method according to an exemplary embodiment of the invention.

FIG. 7 is a flowchart illustrating a method for magnetic resonance imaging according to an exemplary embodiment of the invention.

FIG. 8 schematically illustrates a magnetic resonance system according to an exemplary embodiment of the invention.

### DESCRIPTION OF THE PREFERRED EMBODIMENTS

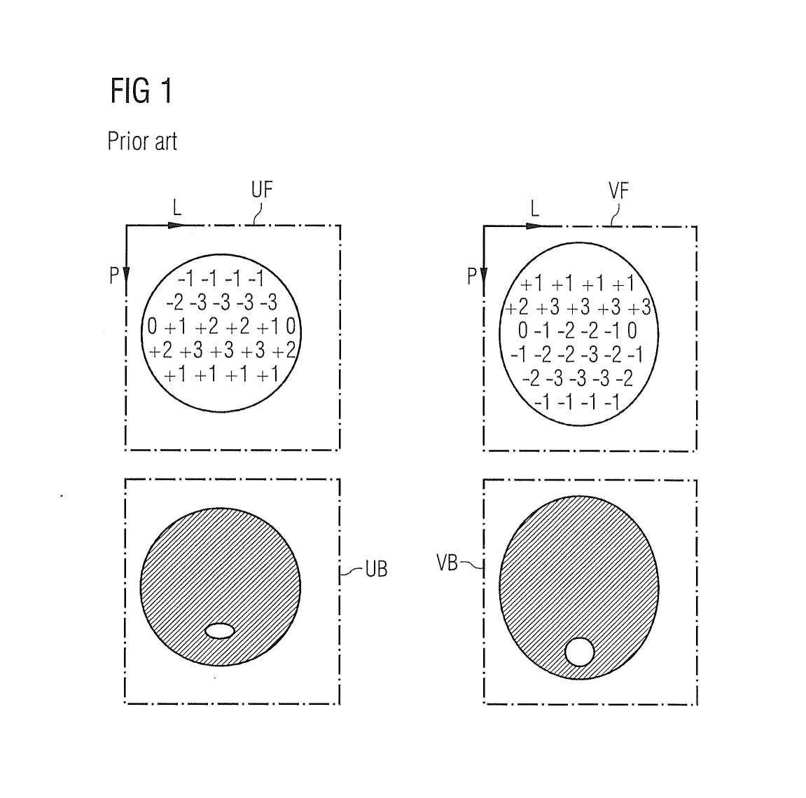

The top left of FIG. 1 shows an undistorted field map, i.e. a field map UF with undistorted coordinates. The ordinate designated P corresponds to the phase encoding direction of the imaging method during the compilation of the undistorted field map and the abscissa designated L corresponds to the readout direction of the imaging method used during the compilation of the undistorted field map. An undistorted field map is obtained with the use of a phase difference formation of a gradient echo sequence. The numbers in the map indicate a displacement at a specific point in pixels by the specified value. The displacement in the image space corresponds to off-resonances of the measuring signals in k-space.

The circular shape indicated in the undistorted field map UF is intended to indicate that there is no distortion of the coordinates with this map. Also shown at the top right is a distorted field map, i.e. a field map VF with distorted coordinates. Here, once again the numbers marked in the map VF indicate a displacement at a specific point in pixels by the specified value. This displacement in the image space corresponds to off-resonances of the measuring signals in the k-space. A distorted field map is obtained with the use of the PLACE method. The bottom left of FIG. 1 shows an undistorted image recording UB compiled with a gradient echo method. Similarly to the undistorted field map UF, a circle is shown in the undistorted recording UB to symbolize that this is an undistorted recording even though it may contain artifacts. The bottom right of FIG. 1 shows an image recording VB generated with the use of an echo planar sequence. This image recording is an image recording with distorted coordinates and this is symbolized in the image at the bottom right with an ellipse.

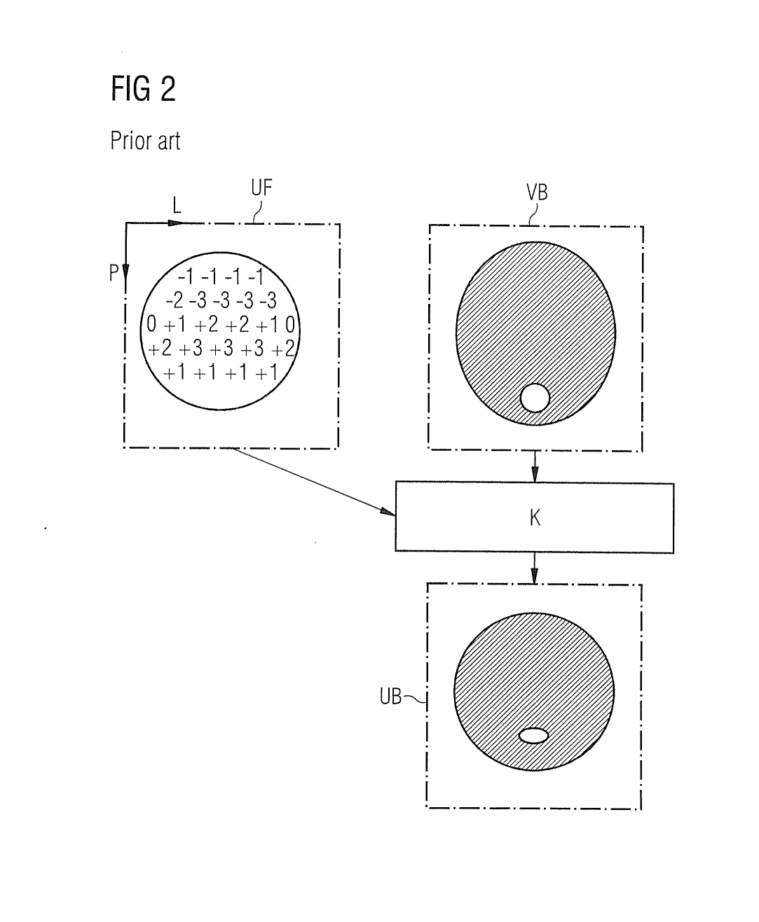

FIG. 2 shows the geometric correction of an image VB acquired for example with an EPI sequence with the use of an undistorted field map UF. The top left shows an undistorted field map UF. The top right shows the distorted image VB of an object, in this case a circle, acquired with an EPI sequence, depicted distorted as an ellipse. The undistorted field map UF is used to apply a correction method K to the distorted image recording. The correction method K can, for example, be a correction method based on the conjugate phase method. The result of the correction can be identified at the bottom right in FIG. 2 as an undistorted image reproduction UB of a circle.

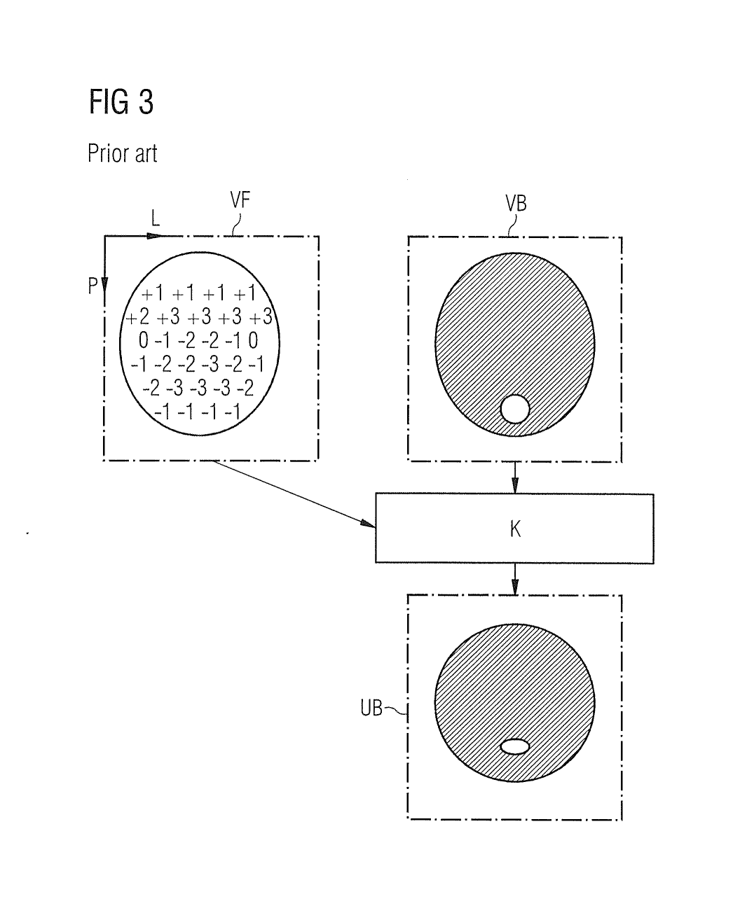

FIG. 3 shows the geometric correction of a distorted image VB of a circle acquired with an EPI sequence with the use of a distorted field map VF. The recording of the distorted field map VF can be performed, for example, with the use of the PLACE method. The top left symbolizes a distorted field map VF with the aid of an ellipse. The numerical values shown in the ellipse correspond to displacement values of the pixels arranged in the distorted field map VF, which have become displaced due to field inhomogeneities. The top right of FIG. 3 shows a distorted depiction VB of a recorded image of a circle symbolically as an ellipse. The bottom right shows a corrected recorded image UB symbolically as a circle. The correction of the distorted image VB at the top right with the aid of the distorted field map VF at the top left can be performed, for example, with a correction method K including bilinear interpolation.

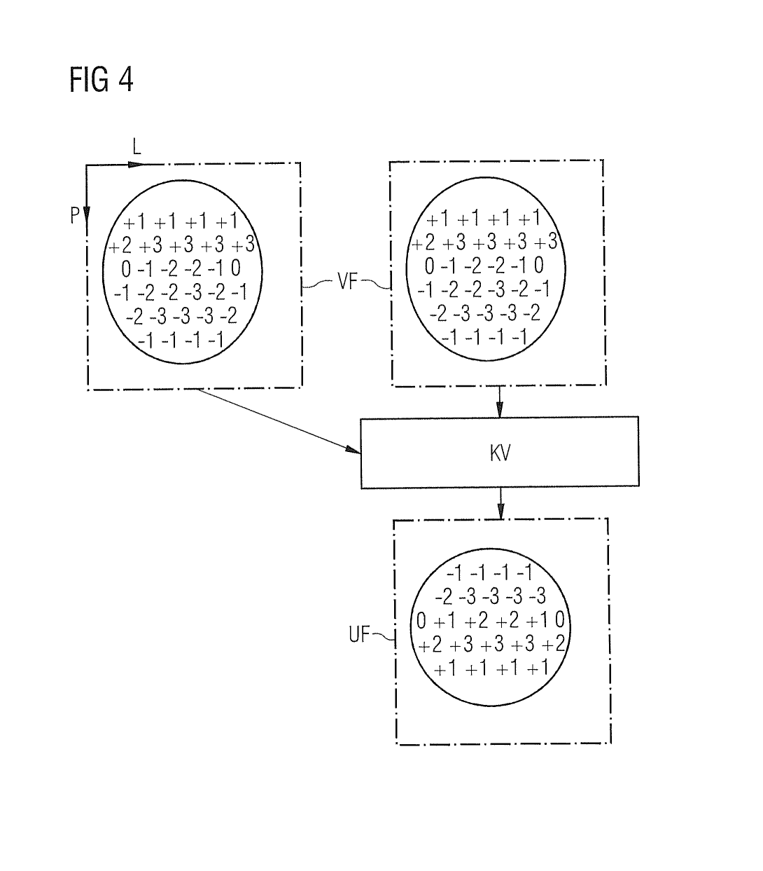

FIG. 4 shows the same distorted field map VF at the top left and top right. The distorted field map VF is again symbolized by an ellipse containing numerical values corresponding to displacement values of the pixels arranged in the distorted field map VF, which have become displaced due to field inhomogeneities. The bottom right of FIG. 4 shows an undistorted field map UF containing the numerical values corresponding to displacement values of the pixels arranged in the distorted field map, which have become displaced due to field inhomogeneities.

FIG. 4 is intended to illustrate the conversion of a distorted field map VF in an undistorted field map UF. For this purpose, a distorted field map VF is applied to itself. In this case, the conversion method KV used is, for example, the PREFICS method.

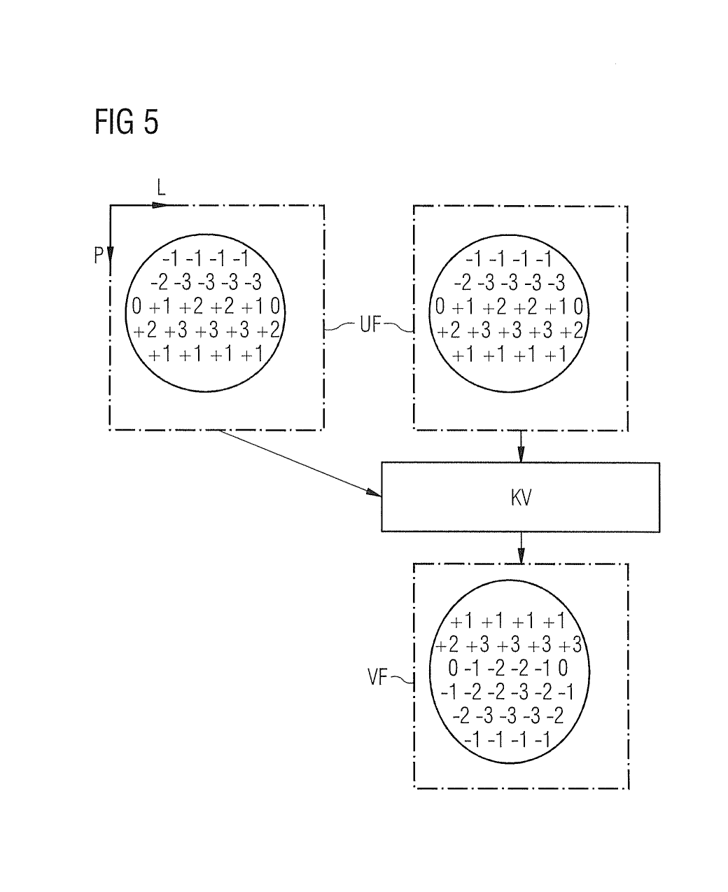

FIG. 5 shows a method for the conversion of an undistorted field map UF into a distorted field map VF such as is part of a method for the correction of image data acquired using a magnetic resonance imaging method according to an exemplary embodiment of the invention. The top right and top left in FIG. 5 show the same undistorted field map UF, which is symbolized with a circle. The numbers shown in the map indicate a displacement at a specific point in pixels by the specified value. The bottom right shows a distorted field map VF symbolized as an ellipse. The conversion of the undistorted field map UF into a distorted field map VF is performed by application to itself. The conversion method KV used be, for example, bilinear interpolation on the basis of the undistorted field map UF.

The method according to an exemplary embodiment of the invention is then continued with the correction of a distorted image recording VB with the aid of the distorted field map VF obtained, such as that shown in FIG. 3. The correction K of the distorted image recording VB with the aid of the distorted field map VF can then be performed by means of bilinear interpolation corresponding to the PLACE method. The method according to the invention offers the possibility of choosing among different correction methods for the correction of distorted image recordings. For example, it is possible to choose between the conjugate phase method and the PLACE method as correction methods depending upon whether the correct is based on a distorted or an undistorted field map. For example, the conjugate phase method has the advantage that it can be based on recordings with any k-space trajectories. The PLACE method in turn has the advantage that the recording of the distorted field maps or the bilinear interpolation applied thereby is much less complicated than conjugate phase methods since the latter necessitates the execution of a very large number of Fourier transformations requiring high processing capacity, which is not required with interpolation in the image domain.

Moreover, the use of bilinear interpolation as correction method means the recording method for a source field map is not restricted to the PLACE method. Alternatively, the source field card can also be obtained with a double- or multi-gradient echo recording and then conversion of the source field card performed with the aid of bilinear interpolation. Alternatively, conversion of the undistorted field map into a distorted with the aid of the conjugate-phase method would be possible.

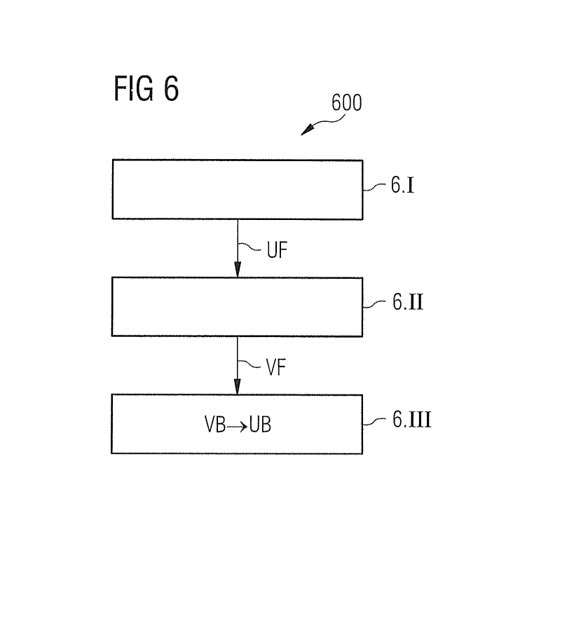

FIG. 6 is a flowchart illustrating a method 600 for the correction of image data acquired using a magnetic resonance imaging method according to an exemplary embodiment of the invention. In Step 6.I, an undistorted B₀ field map UF is acquired. This can, for example, be done with the aid of a gradient echo method. In Step 6.II, the undistorted B₀ field map UF is converted into a distorted B₀ field map VF. The conversion step can be based, for example, on bilinear interpolation. Finally, in Step 6.III, image data VB recorded with distorted coordinates is corrected with the aid of the distorted B₀ field map VF. The correction is, for example, performed using the PLACE method or a method based thereupon or similar thereto.

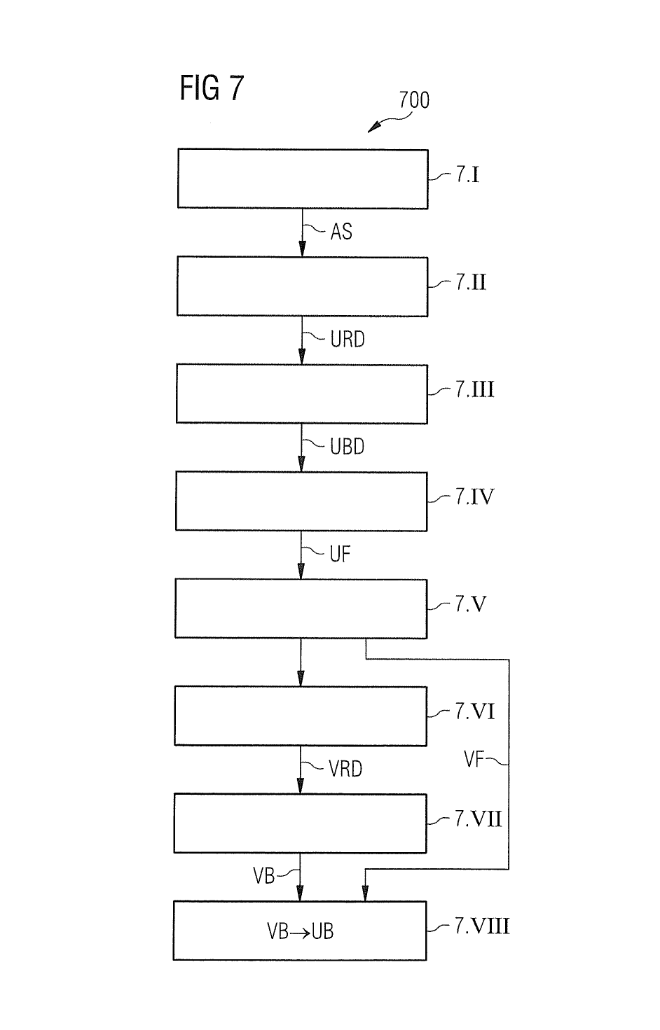

In FIG. 7, a flowchart is shown to illustrate a method 700 for magnetic resonance imaging according to an exemplary embodiment of the invention. With the method according to an exemplary embodiment of the invention, initially in Step 7.I, a control sequence AS is generated on the basis of protocol data, said control sequence comprising as partial sequences both a first partial sequence to generate an undistorted field map UF and a second partial sequence to generate a distorted image recording VB of a partial region of the body of an object to be examined. The sequence to generate an undistorted field map UF can be a gradient echo sequence, for example. The sequence to generate a distorted image recording VB of a partial region of the body of an object to be examined can, for example, be an EPI sequence.

In Step 7.II, the first partial sequence of the control sequence AS is used to acquire raw data URD for an undistorted field map UF. In Step 7.III, the raw data URD acquired is reconstructed into image data UBD. This can be done with a Fourier transformation. Phase image data are required for the compilation of the image data for field maps. These are obtained from the Fourier transformations of the measuring signals or raw data acquired in the complex space. In Step 7.IV, an undistorted field map UF is generated on the basis of the image data UBD determined. This can be implemented, for example, by phase difference formation, wherein the difference from different phase images is determined. In Step 7.V, the undistorted field map UF is converted into a distorted field map VF. This can, for example, take place with the use of bilinear interpolation. In Step 7.VI, the second partial sequence for generating a distorted image recording VB of a partial region of the body of an object to be examined is used to perform the still distorted image recording of a partial region of the body of the object to be examined. In Step 7.VII, the measured data initially present as raw data VRD are transformed into the image space. Finally, in Step 7.VIII, the distorted image data VB is converted with the aid of the distorted field map VF. The correction step can be done using the PLACE method, for example. In this case, image data UB is generated with undistorted, i.e. non-displaced coordinates.

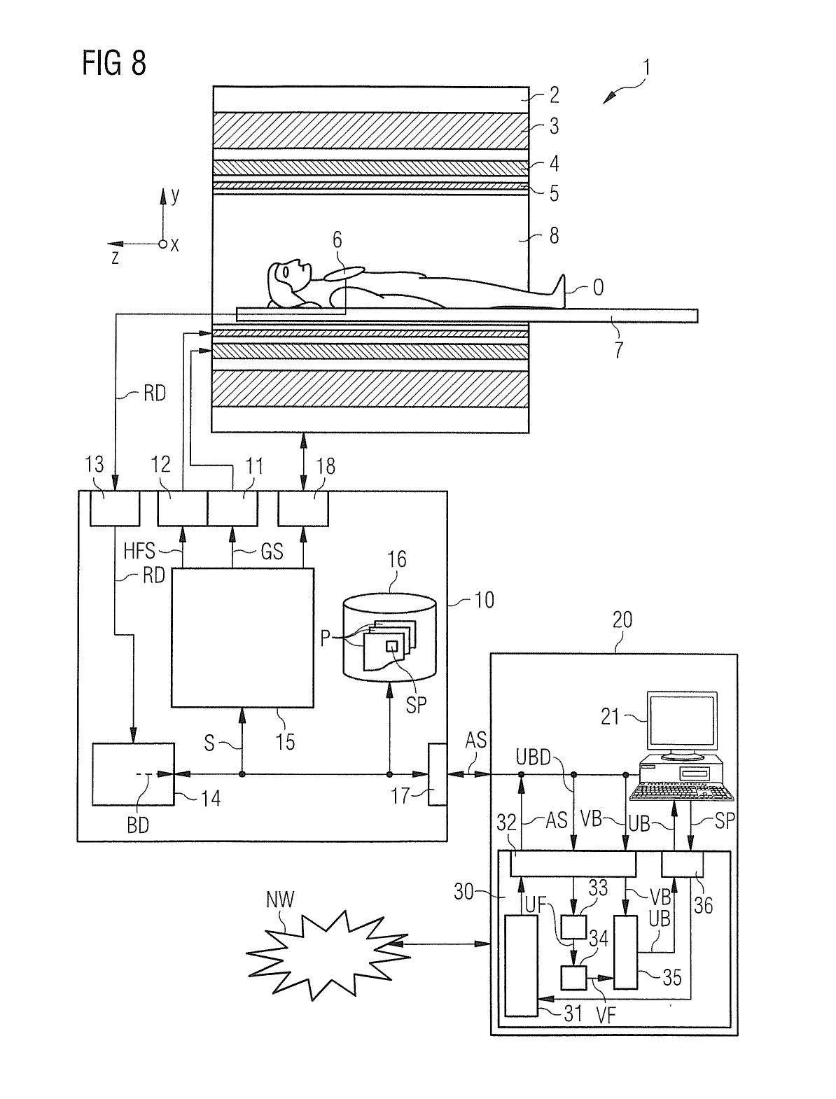

FIG. 8 shows a magnetic resonance apparatus 1 according to an exemplary embodiment of the invention. This apparatus has the actual magnetic resonance scanner 2 within which there is an examination chamber 8 or patient tunnel. A table 7 may be moved into this patient tunnel 8 so that patient O or test subject lying thereon may be placed at a specific position within the magnetic resonance scanner 2 during an examination relative to the magnetic system and radio frequency system arranged therein or may also be moved between different positions during a measurement.

Here, the components of the magnetic resonance scanner 2 include a basic field magnet 3, a gradient system 4 with magnetic field gradient coils to generate magnetic field gradients in the x-, y- and z-directions and a whole-body radio-frequency coil 5. The magnetic field gradients in the x-, y- and z-directions (spatial coordinate system) can be controlled independently of each other so that, using a prespecified combination, gradients can be applied in any spatial direction, for example in a slice selection direction, a phase encoding direction or a readout direction, which do not necessarily lie parallel to the axes of the spatial coordinate system. The magnetic resonance signals induced in the object under examination 0 can be received by the whole-body coil 5, with which as a rule the radio-frequency signal are also emitted to induce the magnetic resonance signals. However, these signals are usually received by a local coil arrangement 6 with, for example, local coils (of which only one is shown here) placed on or under the patient O. All these components are known in principle to the person skilled in the art and therefore they are only depicted in a simplified schematic view in FIG. 8.

The components of the magnetic resonance scanner 2 can be controlled by a control computer 10. This computer may be formed of multiple individual computers or processors that may optionally be spatially separate and connected to each other by suitable cables or the like. A terminal interface 17 connects these control computer 10 to a terminal 20 via which an operator can control the entire system 1. In the present case, this terminal 20 has a computer 21 with a keyboard, one or more screens and further input devices, for example, a mouse or the like or is embodied as a computer 21 of this kind so that a graphical user interface is available to the user.

The control device 10 has, inter alia, a gradient control processor 11 which in turn may be composed of a multiple subcomponents. This gradient control unit 11 switches the individual gradient coils in accordance with a gradient-pulse sequence GS with control signals. As described above, these are gradient pulses that are set during a measurement at precisely defined temporal positions and with a precisely defined temporal course.

The control computer 10 also has a radio-frequency transmitter unit 12 in order to supply the whole-body radio-frequency coil 5 with radio-frequency pulses in accordance with a prespecified radio-frequency pulse sequence HFS of the control sequence AS. The radio-frequency pulse sequence HFS includes the aforementioned selective excitation pulses. The reception of the magnetic resonance signals then takes place with the aid of the local coil arrangement 6 and the raw data RD received thereby are read out and processed by an RF receive unit 13. After demodulation and digitization in digital form, the magnetic resonance signals are transmitted as raw data RD to a reconstruction unit 14, which reconstructs the image data BD therefrom and stores this in a memory 16 and/or transfers it via the interface 17 to the terminal 20 so that it can be viewed by the operator. The image data BD can also be stored, and/or displayed and evaluated at other locations via a network NW. Alternatively, a radio-frequency pulse sequence can also be transmitted via the local coil arrangement and/or the magnetic resonance signals can be received by the whole-body radio-frequency coil (not shown).

A further interface 18 sends control commands to other components of the magnetic resonance scanner 2, such as, for example, the table 7 or the basic field magnet 3 or accepts measured values or other information.

The gradient control unit 11, the RF-transmitter 12 and the RF-receive unit 13 are each controlled in a coordinated manner by a measurement control computer 15. This uses appropriate commands to ensure that the desired gradient pulse sequence GS and radio-frequency pulse sequence HFS of the control sequence AS are transmitted. It is also necessary to ensure that the magnetic resonance signals at the local coils of the local coil arrangement 6 are read out and further processed by the RF receive unit 13 at the correct time, i.e. readout windows must be set in that, for example, the ADCs of the RF receive unit 13 are set to receive. The measurement control unit also 15 controls the interface 18.

The basic procedure of a magnetic resonance measurement of this kind and the aforementioned control components are known to those skilled in the art, and thus need not be discussed in further detail herein. Otherwise, a magnetic resonance scanner 2 of this kind and the associated control device 10 can also have a number of further components that are likewise known and thus are not explained in detail herein. The magnetic resonance scanner 2 may have a different design, for example with a side-opening patient chamber or as a smaller scanner in which only one body part can be positioned.

To start a measurement, an operator can usually use the terminal 20 to select a control protocol P intended for this measurement from a memory in which a number of control protocols P is stored for different measurements. This control protocol P includes, inter alia, different control parameter values SP for the respective measurement. These control parameter values SP also include, for example, the type of sequence, the target magnetization for the individual radio-frequency pulses, echo times, repetition times, the different selection directions etc.

All these control parameter values SP are, inter alia, made available to an image correction processor 30 via a first interface 36 enabling this to generate a suitable control sequence or a sequence of control sequences AS corresponding to the method according to the invention. To this end, the image correction device 30 comprises a control sequence-generating unit 31 which generates a sequence AS with a gradient echo sequence for the generation of an undistorted field map and a subsequent EPI sequence for the actual image recording of a body region of a patient.

Otherwise, the operator can also retrieve control protocols from the memory 16 via a network NW, for example, from a manufacturer of the magnetic resonance system, with corresponding control parameter values SP and then use these as described below.

Based on the control parameter values SP, the image correction computer 30 determines a control sequence sequencing AS according to which the control of the other components by the measurement control unit 15 finally takes place. According to the control sequence sequencing AS, initially, an undistorted field map of a partial area of the body of the patient is acquired, for example, with the use of a gradient echo sequence. The raw data URD generated are reconstructed, by the execution of a reconstruction algorithm in reconstruction unit 14, into undistorted image data UBD and transmitted via a second interface unit 32 of the image correction device 30 to a field map reconstruction unit 33. To this end, the field map reconstruction unit 33 is configured on the basis of the undistorted image data UBD generated with the gradient echo method to compile an undistorted field map UF. The field map UF generated is forwarded to a field map conversion unit 34, which converts the undistorted field map UF into a distorted field map VF. The data assigned to the distorted field map VF is forwarded to an image correction unit 35. Furthermore, according to the control sequence sequencing AS, a distorted image recording of a partial region of the body of the patient is produced, for example with the aid of an EPI sequence. The distorted image data VBD is transmitted via the second interface 32 of the image correction device 30 to the image correction unit 35. The image correction unit 35 now corrects the distorted image data VB with the aid of the distorted field map VF. This is done, for example, using the PLACE method. Then, the data of the corrected image UB is transmitted via the first interface 36 of the image correction device 30 to the computer 21 and further processed and, for example, displayed thereby.

The entire image correction device 30 and its components can, for example, be implemented in the form of software with which the method according to the invention on one or more suitable processors.

The method and devices described above in detail are exemplary embodiments and that the basic principle can be varied in wide ranges by those skilled in the art without departing from the scope of the invention. For example, instead of in the terminal, the image correction device 30 can be implemented as part of the control computer 10 or on the computer 21 or on a separate computing system, which is, for example, connected to the magnetic resonance apparatus 1 via the network NW. Also the spatial directions can be varied as desired, i.e. the x- and y-directions can be transposed.

For completeness, the use of the indefinite article “a” or “an” does not preclude the possibility of the features designated thereby being present on a multiple basis. Similarly, the term “unit” does not preclude the possibility of this comprising a plurality of components that may also be spatially distributed.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for correcting magnetic resonance (MR) image data, comprising:
providing a processor with MR image data acquired from a subject by execution of an MR data acquisition sequence in an MR scanner in which the object is situated, with a basic magnetic (B₀) field being present in said MR scanner during acquisition of said MR image data that causes said MR image data to be acquired with distorted coordinates;
providing said processor with an undistorted B₀ field map;
in said processor, converting said undistorted B₀ field map into a distorted B₀ field map; and
in said processor, using said distorted B₀ field map to correct said MR image data, acquired with said distorted coordinates, to obtain corrected MR image data, and making the corrected MR image data available from the processor in electronic form as a datafile.

2. A method as claimed in claim 1 comprising converting said undistorted B₀ field map into said distorted B₀ field map by a procedure selected from the group consisting of bilinear interpolation and a conjugate phase method.

3. A method as claimed in claim 1 comprising using bilinear interpolation to correct said MR image data acquired with said distorted coordinates.

4. A method as claimed in claim 1 comprising generating said undistorted B₀ field map by operating said MR scanner with a gradient echo sequence.

5. A method as claimed in claim 4 comprising selecting said gradient echo sequence from the group consisting of a double gradient echo sequence and a multi-gradient echo sequence.

6. A method as claimed in claim 1 comprising acquiring said undistorted B₀ field map in a preliminary procedure before acquiring said MR image data with said distorted coordinates.

7. A method for magnetic resonance (MR) imaging, comprising:
operating an MR scanner to acquire MR image data from a subject by execution of an MR data acquisition sequence in the MR scanner in which the object is situated, while generating a basic magnetic (B₀) field in said MR scanner during acquisition of said MR image data that causes said MR image data to be acquired with distorted coordinates;
providing a processor with said MR image data;
providing said processor with an undistorted B₀ field map;
in said processor, converting said undistorted B₀ field map into a distorted in B₀ field map;
in said processor, using said distorted B₀ field map to correct said MR image data, acquired with said distorted coordinates, to obtain corrected MR image data; and
in said processor reconstructing MR image data from the corrected MR image data and making the MR image data available from the processor in electronic form as a datafile.

8. A method as claimed in claim 7 comprising acquiring said MR image data with distorted coordinates by operating said MR scanner with an echo planar imaging sequence.

9. A magnetic resonance (MR) data correction device, comprising:
a processor that receives MR image data acquired from a subject by execution of an MR data acquisition sequence in an MR scanner in which the object is situated, with a basic magnetic (B₀) field being present in said MR scanner during acquisition of said MR image data that causes said MR image data to be acquired with distorted coordinates;
said processor being provided with an undistorted B₀ field map;
said processor being configured to convert said undistorted B₀ field map into a distorted in B₀ field map; and
said processor being configured to use said distorted B₀ field map to correct said MR image data, acquired with said distorted coordinates, to obtain corrected MR image data, and to make the corrected MR image data available from the processor in electronic form as a datafile.

10. A magnetic resonance (MR) apparatus comprising:
an MR scanner comprising a basic field magnet that generates a basic magnetic (B₀) field;
a processor configured to operate the MR scanner to acquire MR image data from a subject by execution of an MR data acquisition sequence in said MR scanner in which the object is situated, with said B₀ field being present in said MR scanner during acquisition of said MR image data that causes said MR image data to be acquired with distorted coordinates;
said processor being configured to operate said MR scanner to obtain an undistorted B₀ field map;
said processor being configured to convert said undistorted B₀ field map into a distorted in B₀ field map; and
said processor being configured to use said distorted B₀ field map to correct said MR image data, acquired with said distorted coordinates, to obtain corrected MR image data, and to make the corrected MR image data available from the processor in electronic form as a datafile.

11. A non-transitory, computer-readable data storage medium encoded with programming instructions, said storage medium being loaded into a computer and said programming instructions causing said computer to:
receive magnetic resonance (MR) image data acquired from a subject by execution of an MR data acquisition sequence in an MR scanner in which the object is situated, with a basic magnetic B₀ field being present in said MR scanner during acquisition of said MR image data that causes said MR image data to be acquired with distorted coordinates;
receive an undistorted B₀ field map;
convert said undistorted B₀ field map into a distorted in B₀ field map; and
use said distorted B₀ field map to correct said MR image data, acquired with said distorted coordinates, to obtain corrected MR image data, and make the corrected MR image data available from the processor in electronic form as a datafile.
